(19) United States
(12) Patent Application Publication
(10) Pub. No.: US 2026/0262556 A1
(43) Pub. Date: Sep. 3, 2026

(54) METHOD AND APPARATUS FOR HYBRID BONDING

(71) Applicant: TOKYO ELECTRON LIMITED, Tokyo (JP)

(72) Inventors: Partha MUKHOPADHYAY, Oviedo, FL (US); H. Jim FULFORD, Marianna, FL (US); Mark I. GARDNER, Cedar Creek, TX (US)

(73) Assignee: TOKYO ELECTRON LIMITED, Tokyo (JP)

(21) Appl. No.: 19/068,970

(22) Filed: Mar. 3, 2025

(51) Int. Cl. H01L 23/00

(52) U.S. Cl. CPC H10W 99/00; H10W 72/011; H10W 72/019; H10W 72/071; H10W 80/301; H10W 80/312; H10W 80/327

(57) ABSTRACT

Aspects of the disclosure provide a hybrid bonding method that includes measuring an overlay registration distribution and a metal recess depth distribution for each of a first wafer and multiple second wafers, the overlay registration distribution of each wafer indicating a distribution of overlay registration values of dies of the respective wafer, and the metal recess depth distribution of each wafer indicating a distribution of metal recess depths of bonding regions of the dies of the respective wafer; based on the overlay registration distributions and the metal recess depth distributions of the first wafer and the multiple second wafers, executing a die pairing process that selects a plurality of dies from the multiple second wafers and pairs the selected plurality of dies with the dies of the first wafer to form a plurality of pairs of dies; and executing an anneal process to bond the plurality of pairs of dies.

### FIELD OF THE INVENTION

The present disclosure relates to semiconductor manufacturing of integrated circuits, and particularly to packaging and stacking of dies as a technique for transistor stacking or 3D formation of semiconductors.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

Aspects of the disclosure provide a hybrid bonding method. The hybrid bonding method includes measuring an overlay registration distribution and a metal recess depth distribution for each of a first wafer and multiple second wafers, the overlay registration distribution of each wafer indicating a distribution of overlay registration values of dies of the respective wafer, and the metal recess depth distribution of each wafer indicating a distribution of metal recess depths of bonding regions of the dies of the respective wafer; based on the overlay registration distributions and the metal recess depth distributions of the first wafer and the multiple second wafers, executing a die pairing process that selects a plurality of dies from the multiple second wafers and pairs the selected plurality of dies with the dies of the first wafer to form a plurality of pairs of dies; and executing an anneal process to bond the plurality of pairs of dies.

Aspects of the disclosure provide a hybrid bonding system. The hybrid bonding system includes a controller configured to control a measurement system to measure an overlay registration distribution and a metal recess depth distribution for each of a first wafer and multiple second wafers, the overlay registration distribution of each wafer indicating a distribution of overlay registration values of dies of the respective wafer, and the metal recess depth distribution of each wafer indicating a distribution of metal recess depths of bonding regions of the dies of the respective wafer; based on the overlay registration distributions and the metal recess depth distributions of the first wafer and the multiple second wafers, control a die pairing system to execute a die pairing process that selects a plurality of dies from the multiple second wafers and pairs the selected plurality of dies with the dies of the first wafer to form a plurality of pairs of dies; and control an anneal system to execute an anneal process to bond the plurality of pairs of dies.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 shows a flow chart of a process for manufacturing a semiconductor device, in accordance with some embodiments of the present disclosure.

FIG. 2A shows an overlay registration distribution of a top wafer in accordance with some embodiments of the present disclosure.

FIG. 2B shows an overlay registration distribution of a bottom wafer in accordance with some embodiments of the present disclosure.

FIG. 2C shows a schematic view of a die pairing process in accordance with some embodiments of the present disclosure.

FIG. 2D shows a schematic view of a die pairing process in accordance with some embodiments of the present disclosure.

FIG. 3A shows a schematic view of a die pairing process in accordance with some embodiments of the present disclosure.

FIG. 3B shows a schematic view of a die pairing process in accordance with some embodiments of the present disclosure.

FIG. 4 shows a flow chart of a process for manufacturing a semiconductor device in accordance with some embodiments of the present disclosure.

FIG. 5 shows a hybrid bonding system in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

A numerical range represented by “to” includes numerical values at both ends, unless specified otherwise.

Power, Performance, Area, and Cost (PPAC) improvements and Moore's Law's logarithmic performance increases in semiconductor devices have historically progressed primarily through aggressive doubling of transistor count every 18 months enabled by dimensional shrink without regard to functional chip type or the proper management of power scaling and heat dissipation. In the past two decades, as the industry has moved away from fully integrated large silicon area systems on chip (SoCs), it has become increasingly important for continual improvement in semiconductor devices to develop via optimizing PPAC at the system integration level through advanced packaging technologies. These technologies enable different functional chip types (such as “chiplets”) to be integrated into a single package and/or memory chips to be stacked vertically along with controller devices.

An important packaging technology for meeting the industry's ever-increasing needs is hybrid bonding. The Hybrid bonding can be typically executed at bond wiring levels or structures of two opposing dies (or wafers). The hybrid bonding can involve bonding a die to a die (referred to as die-to-die or D2D bonding), a die to a wafer (referred to as die-to-wafer or D2W bonding), or a wafer to a wafer (referred to as wafer-to-wafer or W2W bonding). Each of the two opposing dies/wafers (e.g., two opposing dies, two opposing wafers, or one die and one opposing wafer) has a bonding region including exposed or uncovered dielectric material and conductive material (e.g., metal). Thus, through the hybrid bonding, the dielectric materials of the bonding regions of the two opposing dies/wafers can be bonded together, and the metals of the bonding regions of the two opposing dies/wafers can be bonded together, resulting in dielectric-to-dielectric bonds and metal-to-metal bonds. The hybrid bonding can involve an annealing process which results in expansion of the metals of the opposing dies/wafers so that the metals of the bonding regions of the two opposing dies/wafers can be bonded together. After the hybrid bonding, a substrate wafer can then be singulated to produce packaged modules.

The bonding region can be formed with various wiring techniques. For example, one of the wiring techniques includes forming lines and/or vias in a dielectric material (e.g., silicon oxide), depositing a metal material such as copper (Cu) using an overfill technique, and then using a planarization process such as chemical-mechanical polishing (CMP) to remove an overburden of the metal material. The planarization process does not only remove the overburden of the metal material, but also results in the metal material of a bonding region having a recess below a bonding surface (or a top surface) of the dielectric material of the bonding region. Having the recess for the metal of the bonding region can be advantageous because the metal-to-metal bonds of the bonding regions of the two opposing dies/wafers can be realized using an annealing process. Through the annealing process, the metals of the bonding regions of the two opposing dies/wafers can respectively expand and then contact to each other, until the physical connection and the metal-to-metal bond between the metals are established, thereby providing electric connections between the two opposing dies/wafers.

The challenge, however, is that variations of the recesses of the metals of the bonding regions over a surface area of a wafer (such as a 200 mm or 300 mm wafer) are inevitable. Such recess variations can lead to various post-oxide bonding recess gaps in the hybrid bonding. As such, batch annealing under the same temperature and time results in dissimilarities in the metal-to-metal (e.g., Cu-to-Cu) bonds. The dissimilarities provide either not enough expansion for the metal so that the metal fails to form a connection, or too much expansion causing the metal to enter the bonding surface of the dielectric material, leading to a yield reduction of the hybrid bonding. Moreover, the performance of the bonded dies in terms of electrical characteristics is also compromised.

In the hybrid bonding, a pick-and-place process refers to a robotic process of grasping a top die, positioning the top die onto a bottom die, and aligning bonding regions of the top die to the corresponding bonding regions of the bottom die, so that the top and bottom dies, which form a pair of dies, can be bonded together. The pick-and-place process can be executed by various robots (e.g., a robotic arm) and is designed to operate in a cleanroom and to significantly reduce manufacturing time and improve manufacturing quality.

Because the hybrid bonding forms electrical connections that electrically connects both the top and bottom dies, ensuring that the electrical connections are aligned and properly formed is crucial for a yield improvement of the hybrid bonding.

However, a common issue encountered during the hybrid bonding is a misalignment between the top and bottom dies. The misalignment can often be resulted from a flattening process of a wafer having a wafer bow. The wafer bow of the wafer can be flattened by means of stress or strain on the wafer. After the flattening process, the registration (e.g., alignment marks) of the wafer can become inhomogeneous and can be elongated in any direction, potentially leading to a die bonding failure irrespective of correction in alignment. For example, even if an overall alignment of the wafer is correct, an alignment mark of a die on the wafer can still be elongated or distorted. As a result, the top and bottom dies cannot be perfectly aligned, creating a registration mismatch between the top and bottom dies. Such misalignment can lead to defects in the circuit, affecting the performance and yield of the semiconductor devices.

The issue arises when the registration of a die is not taken care of during a pick-and-place process of the hybrid bonding. The registration may match at a center of the die, but may be off at an edge of the die. A registration value of the die, which can be represented by x and y dimensions, changes due to the stress during the flattening process, thereby changing the registration at the edge of the die. This can lead to defects in the circuit, affecting the performance and yield of the semiconductor devices. Therefore, proper overlay registration is crucial to ensure that the features on a top die are correctly positioned relative to the corresponding features on a bottom die that is underneath the top die.

As device geometries shrink with advanced technology nodes, the tolerance for overlay errors becomes even smaller, necessitating a more precise alignment. High precision in overlay registration improves the overall yield of functional devices from a wafer. Therefore, there is a need to overcome the problems discussed above. There is a need for a more effective method to ensure a precise alignment during the die bonding process, when considering the wafer registration, overlay registration, and potential for misalignment.

For die-to-wafer bonding, a top wafer is diced or cut to generate multiple top dies and one of the multiple top dies is put onto one of multiple bottom dies on a bottom wafer to form a pair of dies for bonding.

As described above, overlay registrations of the pair of dies need to be taken care of to align the dies perfectly or within an allowable overlay registration range to achieve a successful hybrid bonding. At the same time, an aggregate (or total) metal recess depth (or gap) of the pair of dies needs to be in an allowable metal recess depth range so that a specific anneal temperature used for the hybrid bonding can lead to a successful hybrid bonding. The aggregate metal recess depth of the pair of dies can represent a sum of metal recess depths of the bonding regions of the top and bottom dies.

Therefore, both the allowable ranges have to be considered before grouping the top dies during pick-and-place of the top dies onto the bottom dies. A more complex algorithm needs to be applied to find a distribution of dies and group the dies based on the allowable Cu recess depth mapping and overlay registration mapping.

Aspects of the disclosure provide a method and apparatus for enhancing the yield of functional devices from a wafer. This is achieved by calculating an allowable overlay registration value and a Cu recess depth for each bottom die from a bottom wafer and for each top die from a set of top wafers. A feedback control system with a decision-making algorithm is then employed to distribute a top die over a bottom die based on the calculated allowable overlay registration value and a proximity of Cu recess depth, thereby, grouping them for a specific heat treatment such as an annealing process. The apparatus can incorporate a smart die bonder with an artificial intelligence engine to optimize the group distribution based on the failure analysis of the previous bonding database. This novel and efficient approach significantly improves the overall yield of functional devices, ensuring precise alignment and successful chip-to-wafer hybrid bonding.

According to aspects of the disclosure, the control system in the form of a decision-making algorithm can consider the overlay registration and Cu recess depth of each bottom die in the whole wafer and group them by distributing top dies matching both the overlay registration and Cu recess depth to an allowable range during the pick-and-place die-to-wafer bonding for maximum yield under a specific anneal temperature. For example, the group of wafers can have the same standard deviation (sigma) but a different median Cu-Cu recess gap, thus requiring a different heat treatment. By grouping them the sigma among the wafers can get reduced.

A decision-making algorithm method can be implemented to enhance the yield in a smart die bonder during the die-to-wafer hybrid bonding and the algorithm can input the overlay registration and Cu recess depth of each bottom die in a whole wafer and each top die from multiple wafers which facilitates to grouping them based on the overlay registration matching and proximity of Cu recess depth and thereby, distribute the top die on the bottom die during pick-and-place by matching the allowable range of both overlay registration and Cu recess depth such that the bonded wafer can result in a successful bonding for all bonded dies under a specific heat treatment.

An artificial intelligent (AI) engine (or model or network) in the smart bonder can also optimize the pick-and-place matching distribution based on the failure analysis of the previous bonding database to enhance the yield and prioritize Cu recess depth over overlay registration and vice versa.

In an embodiment, the top die can be an individual die, the bottom die can be an individual die on a full wafer.

The overlay registration ensures that the features on the top die are correctly positioned relative to the features of the underlying bottom die layers, wherein the Cu recess depth among the dies is maintained at the same gap at post-oxide-bonding condition after accounting for the CMP recess variations over the full wafer so that a specific anneal condition can result in a successful bond for each bonded dies. This approach can allow misalignment to successful bonding with considerable contact resistance.

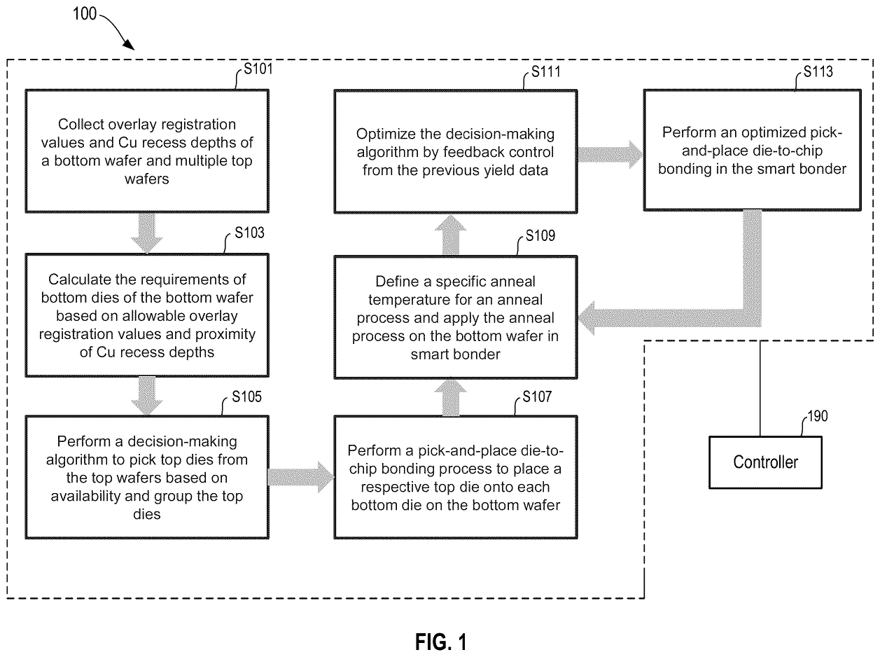

FIG. 1 shows a flow chart of a process 100 for hybrid bonding, in accordance with some embodiments of the present disclosure. At step S101, the process 100 can collect (e.g., through a measurement) overlay registration values and Cu recess depths of a first wafer (also referred to as a bottom wafer) and multiple second wafers (also referred to as top wafers). The dies of the bottom wafer are referred to as bottom dies, and the dies of the top wafers are referred to as top dies. The measurement can be done for each die of the wafers or for a part of the dies of the wafers. At step S103, the process 100 can calculate requirements of the bottom dies of the bottom wafer based on allowable overlay registration values and proximity of Cu recess depths. At step S105, the process 100 can perform a decision-making algorithm to pick the top dies based on availability and group the top dies. At step S107, the process 100 can perform a pick-and-place die-to-chip bonding process. For instance, for each bottom die of the bottom wafer, a top die is picked and placed onto the respective bottom die based on the calculated overlay registration and the proximity of Cu recess depth, so that each bottom die of the bottom wafer has a respective top die placed on the bottom die. At step S109, the process 100 can define a specific anneal temperature for an anneal process and apply the anneal process on the bottom wafer in a smart bonder. At step S111, the process 100 can optimize the decision-making algorithm by feedback control from the previous yield data. At step S113, the process 100 can perform an optimized pick-and-place die-to-chip bonding process in the smart die-bonder, and then go back to the step S109.

In an embodiment, a controller 190 may be coupled to various components of the process 100 to receive inputs from and provide outputs to the components. For example, the controller 190 can be configured to implement the steps S101, S103, S105, S107, S109, S111 and/or S113. In an embodiment, one or more functions of the controller 190 can also be manually accomplished.

In some embodiments, the controller 190 may include a memory storage unit and user interface (all not shown). Components of a semiconductor processing tool (e.g. a bonding tool, a registration metrology tool, etc.) can be connected to and controlled by the controller 190. Various wafer-processing operations can be executed via the user interface, and various wafer processing recipes and operations can be stored in the storage unit.

In an embodiment, the controller 190 may be coupled to various components of various semiconductor processing tools to receive inputs from and provide outputs to the various components. For example, the controller 190 can be configured to receive overlay registration data from a corresponding registration metrology tool. The controller 190 can also be configured to pick a top die from a dicing tape and place the top die onto a bottom die by controlling a robotic arm. The controller 190 can further be configured to adjust knobs and control settings for the corresponding bonding tool. Such adjustments can be manually made as well.

The controller 190 can be implemented in a wide variety of manners. In an example, the controller 190 includes a computer. In an example, the controller 190 includes one or more programmable integrated circuits that are programmed to provide the functionality described herein. For example, one or more processors (e.g. microprocessor, microcontroller, central processing unit, etc.), programmable logic devices (e.g. complex programmable logic device (CPLD)), field programmable gate array (FPGA), etc.), and/or other programmable integrated circuits can be programmed with software or other programming instructions to implement the functionality of a semiconductor processing recipe. It is further noted that the software or other programming instructions can be stored in one or more non-transitory computer-readable mediums (e.g. memory storage devices, FLASH memory, DRAM memory, reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations can also be implemented.

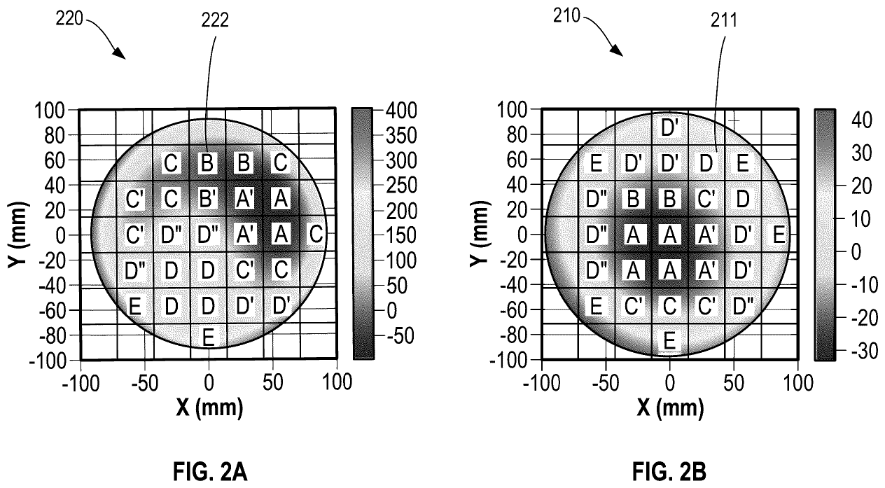

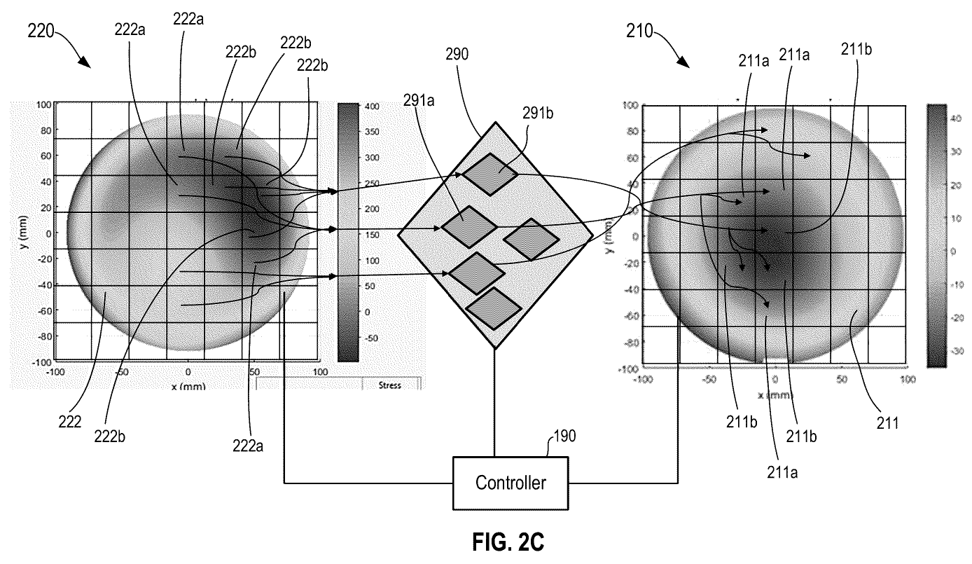

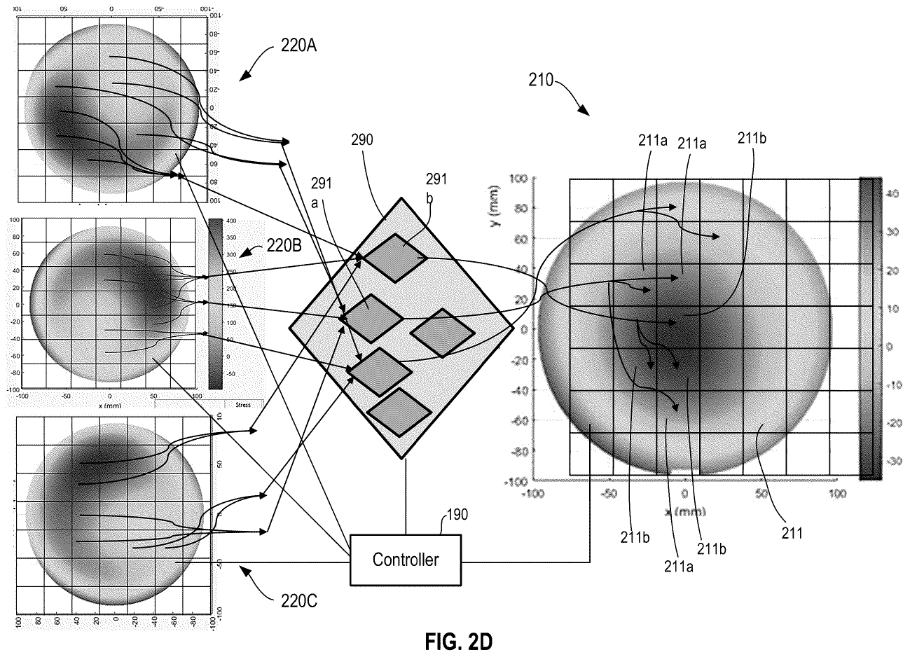

FIG. 2A shows an overlay registration distribution of a top wafer (also referred to as a second wafer 220 hereinafter), and FIG. 2B shows an overlay registration distribution of a bottom wafer (also referred to as a first wafer 210 hereinafter), in accordance with some embodiments of the present disclosure.

The first wafer 210 includes a plurality of first dies 211 arranged in a grid pattern. The first wafer 210 can be flattened to reduce wafer bow. As a result, wafer registration can become inhomogeneous. First overlay registration values (ORVs) of the first dies 211 can be measured by a registration metrology technique including, but not limited to, optical imaging, optical scatterometry, scanning electron microscopy and/or the like. As a result, the first ORVs can be mapped across the first wafer 210. The first dies 211 can be divided into groups based on respective first ORVs.

In the example of FIG. 2B, the first dies 211 can be divided into Group A, Group A′, Group B, Group B′, Group C, Group C′, Group D, Group D′, Group D'′, and Group E, where each group may include one or more of the first dies 211. Respective dies within each group have respective first ORVs that are close to each other, e.g. within a predetermined range.

The second wafer 220 includes a plurality of second dies 222 arranged in a grid pattern. The second wafer 220 can be flattened to reduce wafer bow. As a result, wafer registration can become inhomogeneous. Second ORVs of the second dies 222 can be measured by the same registration metrology technique as the first ORVs or different registration metrology techniques. As a result, the second ORVs can be mapped across the second wafer 220. The second dies 222 can be divided into groups based on respective second ORVs.

In the example of FIG. 2A, the second dies 222 can be divided into Group A, Group A′, Group B, Group B′, Group C, Group C′, Group D, Group D′, Group D'′, and Group E, where each group may include one or more of the second dies 222. Respective dies within each group have second ORVs that are close to each other, e.g. within a predetermined range.

Here, groups of the first dies 211 and groups of the second dies 222 are designated the same letter for having the same or similar ORVs. For instance, respective first ORVs of Group A of the first dies 211 are within a first range while respective second ORVs of Group A of the second dies 222 are within a second range. The first range and the second range can be the same as each other or close to each other such that Group A of the first dies 211 and Group A of the second dies 222 can be treated as having substantially the same ORVs for subsequent processing. Similarly, Group B of the first dies 211 and Group B of the second dies 222 can be treated as having substantially the same ORVs for subsequent processing. More generally speaking, allowable registration matching can be A to A/A′, or B to B/B′, C to C/C′, or D to D/D′/D″, etc. On the other hand, pairing a die from Group B of the second dies 222 with a die from Group A or A′ of the first dies 211 can lead to misalignment and failure of device operation of die-to-chip. The misalignment can become more problematic as the reduction of feature sizes.

Note that although FIGS. 2A and 2B show that the first wafer 210 and the second wafer 220 have different ORV distributions, the first wafer 210 and the second wafer 220 can have the same ORV distribution in an embodiment.

Further, FIGS. 2A and 2B only show one embodiment of dividing the first dies 211 and/or the second dies 222 into groups for illustrative purposes. In other embodiments, depending on specific design needs, the first dies 211 and/or the second dies 222 can be divided into groups differently, for example as will be demonstrated in FIG. 2C.

FIG. 2C shows a schematic view of a die pairing process in accordance with some embodiments of the present disclosure. Herein, the first dies 211 are divided into a first group represented by first dies 211a, a second group represented by first dies 211b, and other groups based on respective first ORVs. The respective first ORVs of the first dies 211 can be measured for example by the aforementioned registration metrology technique, which may further be controlled by the controller 190 and stored in the controller 190.

The controller 190 can include a decision-making algorithm 290 that stores ORV values and/or ranges (e.g. 291a, 291b, etc.) corresponding to groups of the first dies (e.g. 211a, 211b, etc.). The controller 190 can also collect and store respective second ORVs of the second dies 222. The decision-making algorithm 290 can compare the (stored) ORV ranges (e.g. 291a, 291b, etc.) with the second ORVs and accordingly divide the second dies 222 into a first group represented by second dies 222a, a second group represented by second dies 222b, and other groups. For instance, the first group of the first dies represented by the first dies 211a and the first group of the second dies represented by the second dies 222a can be matched and paired for having respective ORVs within a first ORV range 291a. The second group of the first dies represented by the first dies 211b and the second group of the second dies represented by the second dies 222b can be matched and paired for having respective ORVs within a second ORV range 291b.

As a result, any one of the second dies 222a can be picked from the second wafer 220 and placed onto any one of the first dies 211a to form a respective pair for example by a robotic arm controlled by the controlled 190. Similarly, any one of the second dies 222b can be picked from the second wafer 220 and placed onto any one of the first dies 211b to form a respective pair.

In this example, the first dies 211 can be used as bottom dies while the second dies 222 can be used as top dies. That is, the second dies 222 are flipped upside down and placed on top of the first dies 211 so that the first dies 211 and the second dies 222 are oriented face to face. For example, a face side (e.g. circuitry) of the first dies 211 and a face side (e.g. circuitry) of the second dies 222 face towards each other while a back side (e.g. bulk semiconductor material) of the first dies 211 and a back side (e.g. bulk semiconductor material) of the second dies 222 face away from each other.

Note that the second dies 222 have initial relative positions with regard to each other on the second wafer 220. However, after the die pairing or pick-and-place process, the second dies 222 are placed on respective first dies 211 and may have changed relative positions with regard to each other. For instance, two neighboring second dies 222 on the second wafer 220 may not be neighboring to each other after die pairing or pick-and-place process.

In the examples of FIGS. 2A-2C, the first wafer 210 and the second wafer 220 both have a wafer diameter of 200 mm. Generally speaking, the first wafer 210 and the second wafer 220 may each independently have a wafer diameter of 50 mm, 75 mm, 100 mm, 125 mm, 150 mm, 200 mm, 300 mm, or 450 mm. Preferably, the first wafer 210 and the second wafer 220 each independently have a wafer diameter of 150 mm, 200 mm, or 300 mm. Additionally, the first wafer 210 and the second wafer 220 may or may not have a same wafer diameter.

Note that dimensions of various wafer diameters are mentioned herein merely for illustrative purposes and are not limiting. As a skilled artisan would understand, wafer diameters can also be expressed in inches, and a value expressed in millimeters and a value expressed in inches for a same wafer are not always equal to each other. For instance, 50 mm, 75 mm, 100 mm, 125 mm, 150 mm, 200 mm, 300 mm, and 450 mm may respectively be known as 2 inches, 3 inches, 4 inches, 5 inches, 6 inches, 8 inches, 12 inches, and 18 inches. However, 300 mm=11.811 inches, not exactly 12 inches. 200 mm=7.874 inches, not exactly 8 inches. Therefore, a value of a wafer diameter in the present disclosure generally represents a range of the value * (100%±10%), preferably the value*(100%±5%), preferably the value*(100%±3%), preferably the value. For instance, a wafer diameter of 200 mm represents a range of 180 mm to 220 mm, preferably 190 mm to 210 mm, preferably 194 mm to 206 mm, preferably 200 mm.

In a non-limiting example, a plasma activation process can be performed on the first dies 211 and the second dies 222, and deionized water (DIW) may be used to rinse the first dies 211 and the second dies 222. Then the first dies 211 and the second dies 222 can be aligned and pre-bonded. Pre-bonded dies may be inspected, for example using infrared light transmission imaging, and can be stripped and cleaned. The pre-bonded dies can further be bonded for instance by an annealing process. As a result, respective dielectric materials of the first dies 211 and the second dies 222 bond with each other and respective metal materials of the first dies 211 and the second dies 222 expand to bond with each other. It should be understood that the first dies 211 and the second dies 222 may alternatively be bonded by other processes or techniques such as direct bonding, surface-activated bonding, plasma-activated bonding, anodic bonding, eutectic bonding, glass frit bonding, adhesive bonding, reactive bonding, transient liquid phase diffusion bonding, and/or the like.

In the example of FIG. 2C, there are three of the first dies 211a and three of the first dies 211b while there are three of the second dies 222a and four of the second dies 222b. Therefore, the first dies 211a and the first dies 211b can each find a respective match from dies sourced from the second wafer 220 to form a respective pair. In other examples, the second dies 222a may be fewer than the first dies 211a. Additionally or alternatively, the second dies 222b may be fewer than the first dies 211b. Accordingly, one or more additional second wafers may be needed to provide dies for the first dies 211a and/or the first dies 211b. In some embodiments, one or more of the first dies 211 may have respective first ORVs that cannot be matched or paired with any of the second dies 222. Accordingly, one or more additional second wafers will be needed.

Referring back to FIGS. 2A and 2B, there are four dies in Group A, two dies in Group A′, two dies in Group B, zero die in Group B′, one die in Group C, two dies in Group C′, two dies in Group D, five dies in Group D′, four dies in Group D'′, and five dies in Group E in the first dies 211. There are two dies in Group A, two dies in Group A′, two dies in Group B, one die in Group B′, four dies in Group C, three dies in Group C′, four dies in Group D, two dies in Group D′, three dies in Group D″, and two dies in Group E in the second dies 222. Therefore, not all of the first dies 211 can find a match with the second dies 222. Accordingly, one or more additional second wafers will be needed.

FIG. 2D shows a schematic view of a die pairing process in accordance with some embodiments of the present disclosure. Herein, a plurality of second wafers for example represented by 220A, 220B and 220C are used to provide top dies for the first dies 211 sourced from the first wafer 210. For instance, one or more dies, which have respective ORVs that fall within the first ORV range 291a, can be sourced from each of the second wafers 220A, 220B, and 220C, and can be paired with the first dies 211a. Similarly, one or more dies, which have respective ORVs that fall within the second ORV range 291b, can be sourced from each of the second wafers 220A, 220B, and 220C, and can be paired with the first dies 211b.

Here, there are four dies in Group A, two dies in Group A′, two dies in Group B, zero die in Group B′, one die in Group C, two dies in Group C′, two dies in Group D, five dies in Group D′, four dies in Group D'′, and five dies in Group E in the first dies 211. There are six dies in Group A, six dies in Group A′, six dies in Group B, three dies in Group B′, twelve dies in Group C, nine dies in Group C′, twelve dies in Group D, six dies in Group D′, nine dies in Group D″, and six dies in Group E for the second wafers 220A, 220B, and 220C. Therefore, each of the first dies 211 can find a respective match with dies sourced from the second wafers 220A, 220B, and 220C.

The controller 190 can be configured to measure respective second ORVs of second dies sourced from the second wafers 220A, 220B, and 220C, and to store the respective second ORVs. The decision-making algorithm 290 can compare the ORV ranges (e.g., 291a, 291b, and etc.) with the second ORVs and accordingly divide second dies sourced from the second wafers 220A, 220B, and 220C into groups to match and pair with the first dies 211.

Note that the drawings of the present disclosure are not necessarily drawn to scale. Particularly in the example of FIG. 2D, the first wafer 210 and the second wafers 220A, 220B, and 220C all have a same wafer diameter of 200 mm. Generally speaking, the first wafer 210 and the second wafers 220A, 220B, and 220C may each independently have a wafer diameter of 50 mm, 75 mm, 100 mm, 125 mm, 150 mm, 200 mm, 300 mm, or 450 mm. Preferably, the first wafer 210 and the second wafers 220A, 220B, and 220C each independently have a wafer diameter of 150 mm, 200 mm, or 300 mm. Additionally, the first wafer 210 and the second wafers 220A, 220B, and 220C may or may not have a same wafer diameter. In this example, the second wafers 220A, 220B, and 220C have the same ORV distribution. In other examples, at least two of the second wafers 220A, 220B, and 220C can have different ORV distributions.

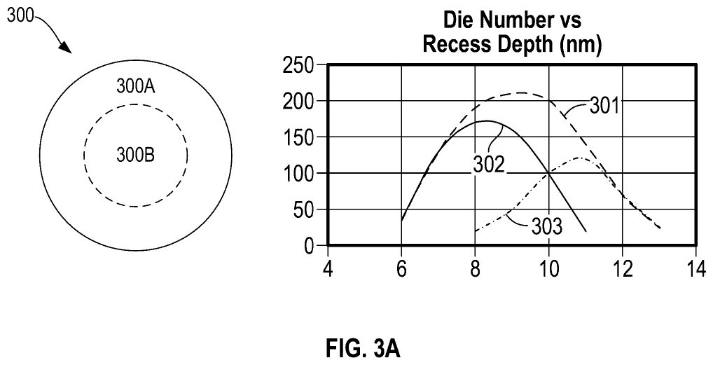

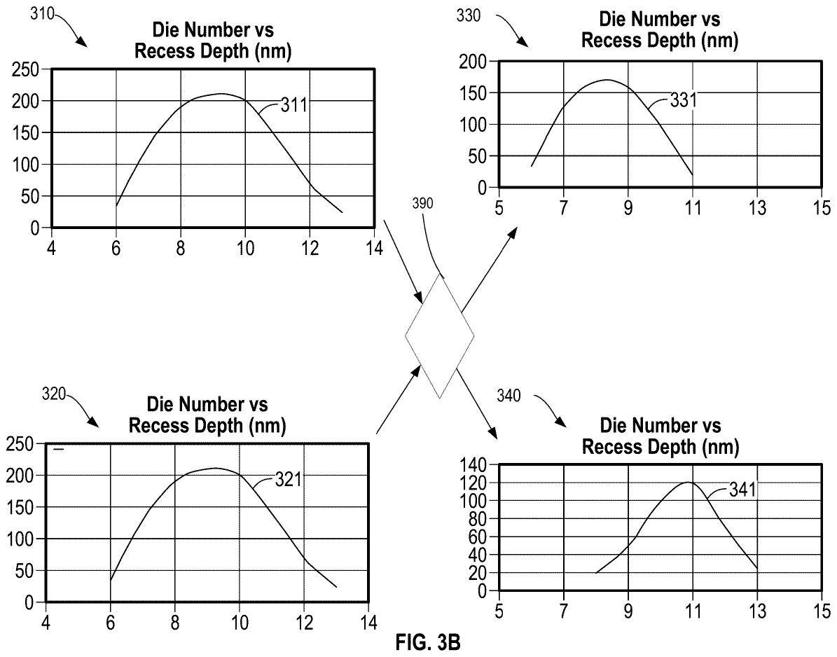

FIG. 3A shows a schematic view of a die pairing process in accordance with some embodiments of the present disclosure. As the CMP can have a higher penetration for metal than a dielectric material surrounding around the metal, a metal recess can be formed after the CMP. Thus, the metal recess variations may require different temperatures to expand the Cu to close the Cu cap and to form the Cu-to-Cu bond between two dies. For example, a lower anneal temperature can be applied on a smaller Cu gap, a higher anneal temperature can be applied on a bigger Cu gap. This process can be referred to as a smart temperature bonding.

In the FIG. 3A example, the plot 301 shows a Cu recess depth distribution of all dies 300 on a top wafer (e.g., the second wafer 220). The X axis and Y axis represent the recess depth in nm and the die number of the top wafer. It can be seen that the Cu recess depth distribution ranges from 6 nm to 13 nm with a median of 9.5 nm.

In an example, in order for each bottom die on a bottom wafer (e.g., the first wafer 210) to have a respective top die from the top wafer to form a pair of dies to be bonded, the dies 300 of the top wafer are randomly placed on the bottom wafer. If the bottom wafer has a same Cu recess depth distribution with the top wafer, then the aggregate Cu recess depths of the pairs of dies can range 12 nm to 26 nm. This range may be too large for an anneal process. That is, if using a common temperature for the anneal process to bond all the pairs of dies on the bottom wafer, some of the pairs of dies may fail to be bonded due to too much Cu expansion or not enough Cu expansion, leading to a low bonding yield. Thus, there is a need to divide the dies 300 into different groups each having a distribution with a smaller range such that the anneal condition can be customized.

In the FIG. 3A example, the dies 300 is divided into two groups 300A and 300B having the Cu recess depth distributions 302 and 303, respectively. The Cu recess depth distributions 302 and 303 can have the same standard derivation (e.g., sigma) and different median values. For example, the Cu recess depth distributions 302 can range from 6 nm to 11 nm with a median value of 8.5 nm, and the Cu recess depth distributions 303 can range from 8 nm to 13 nm with a median value of 10.5 nm. Accordingly, by dividing the dies 300 into groups 300A and 300B, each group of dies can have a smaller range of Cu recess depths, and the sigma of each group can be reduced compared to the whole wafer.

After dividing the top dies 300 into two groups 300A and 300B, only one group of top dies is selected to be paired to the bottom dies on the bottom wafer. Further, when pairing the top dies from the selected group to the bottom dies, the top dies with the Cu recess depths greater than the median value of the Cu recess depth distribution of the selected group can be paired to the bottom dies with the Cu recess depths smaller than the median value of Cu recess depth distribution of the bottom wafer, and the top dies with the Cu recess depths smaller than the median value of the Cu recess depth distribution of the selected group can be paired to the bottom dies with the Cu recess depths greater than the median value of Cu recess depth distribution of the bottom wafer.

For example, when the group 300A is selected to be paired to the bottom dies to form the pairs of dies on the bottom wafer, the dies with the Cu recess depths smaller than the median value (8.5 nm) of the distribution 302 can be paired with and placed onto the bottom dies with the Cu recess depths greater than the median value (9.5 nm) of the distribution 301, and the dies with the Cu recess depths greater than the median value (8.5 nm) of the distribution 302 can be paired with and placed on the bottom dies with the Cu recess depths smaller than the median value (9.5 nm) of the distribution 301. Through this die pairing or pick-and-place process, the aggregate Cu recess depths of the pairs of dies can range from 14.5 nm to 21.5 nm, which is much smaller compared to the range (from 12 nm to 26 nm) of the random picking from the dies 300 for pairing and bonding. Accordingly, a first common anneal temperature (e.g., 300° C.) can be applied to all pairs of dies, leading to a high bonding yield.

Similarly, when the group 300B is selected to be paired to the bottom dies to form the pairs of dies on the bottom wafer, the dies with the Cu recess depths smaller than the median value (10.5 nm) of the distribution 302 can be paired with and placed onto the bottom dies with the Cu recess depths greater than the median value (9.5 nm) of the distribution 301, and the dies with the Cu recess depths greater than the median value (10.5 nm) of the distribution 302 can be paired with and placed on the bottom dies with the Cu recess depths smaller than the median value (9.5 nm) of the distribution 301. Through this die pairing or pick-and-place process, the aggregate Cu recess depths of the pairs of dies can range from 16.5 nm to 23.5 nm, which is much smaller compared to the range (from 12 nm to 26 nm) of the random picking from the dies 300 for pairing and bonding. Accordingly, a second common anneal temperature (e.g., 320° C.) can be applied to all pairs of dies, leading to a high bonding yield.

It can be seen that by dividing the top dies 300 into two groups 300A and 300B, and selecting the top dies from one group to be pair with the bottom dies, the aggregate Cu recess depth distribution of the paired dies can be shrank or tighter and the anneal process can be customized with a specific anneal temperature that can be successfully applied to all paired dies, leading to a high bonding yield.

It is noted that the dividing of the top dies 300 in the FIG. 3A example is merely for illustrative purpose. It is not necessary for the dies 300B to be at the center of the top wafer and surrounded by the dies 300A. Further, a number of groups divided from the top dies 300 is not limited in this disclosure.

In the FIG. 3A example, a number of the top dies from one group is greater than or equal to a number of the bottom dies on the bottom wafer. However, if the number of the top dies from one group is smaller than the number of the bottom dies on the bottom wafer, multiple top wafers can be used, as shown in FIG. 3B.

FIG. 3B shows a schematic view of a die pairing process in accordance with some embodiments of the present disclosure. In the FIG. 3B example, the top wafers 310 and 320 have the same Cu recess depth distribution. Dies on each wafer can be divided into multiple groups such as groups 330 and 340, based on a decision-making algorithm 390, which can include the decision-making algorithm 290 or be included by the decision-making algorithm 290 or independently from the decision-making algorithm 290.

The groups 330 and 340 can have different Cu recess depth distributions. The Cu recess depth distributions of the groups 330 and 340 can have different median values and the same standard derivation. Then, one of the groups (e.g., the group 330) can be selected to be paired with the bottom dies on the bottom wafer. When pairing the top dies from the selected group (e.g., the group 330) to the bottom dies, the top dies with the Cu recess depths greater than the median value of the Cu recess depth distribution (e.g., the distribution 331) of the selected group can be paired to the bottom dies with the Cu recess depths smaller than the median value of Cu recess depth distribution of the bottom wafer, and the top dies with the Cu recess depths smaller than the median value of the Cu recess depth distribution (e.g., the distribution 331) of the selected group can be paired to the bottom dies with the Cu recess depths greater than the median value of Cu recess depth distribution of the bottom wafer, resulting in a tighter distribution for the aggregate Cu recess depths of the paired dies on the bottom wafer.

In an embodiment, the grouping of the dies (e.g., the dies 310 and 320) from one or more top wafers into multiple groups (e.g., the groups 330 and 340) is based on the requirements of the bottom dies, for example, based on the Cu recess depth distribution and/or the overlay registration distribution of the bottom wafer. For example, based on the allowable overlay registration values, the proximity of the Cu recess depths of the bottom dies, and/or the number of the bottom dies, the top dies from one or more top wafers can be selected and grouped to be paired with the bottom dies.

In an embodiment, the selecting and grouping can be performed based on a decision-making algorithm (e.g., the decision-making algorithm 290 or 390) or an artificial intelligent (AI) engine (or model). The AI model can be trained to perform an optimized die pairing process based on the overlay registration distributions and the Cu recess depth distributions of the top and bottom wafers.

In an embodiment, the decision-making algorithm can be optimized by a feedback control from the previous yield data of a bonding process.

Note that a type of a distribution (e.g., the Cu recess depth distribution or the overlay registration distribution) is not limited in this disclosure. For example, the distribution can be a gaussian distribution or any other distribution. The distribution can be measured by a distribution metrology technique including, but not limited to, optical imaging, optical scatterometry, scanning electron microscopy (SEM), atomic force microscopy (AFM), and/or the like.

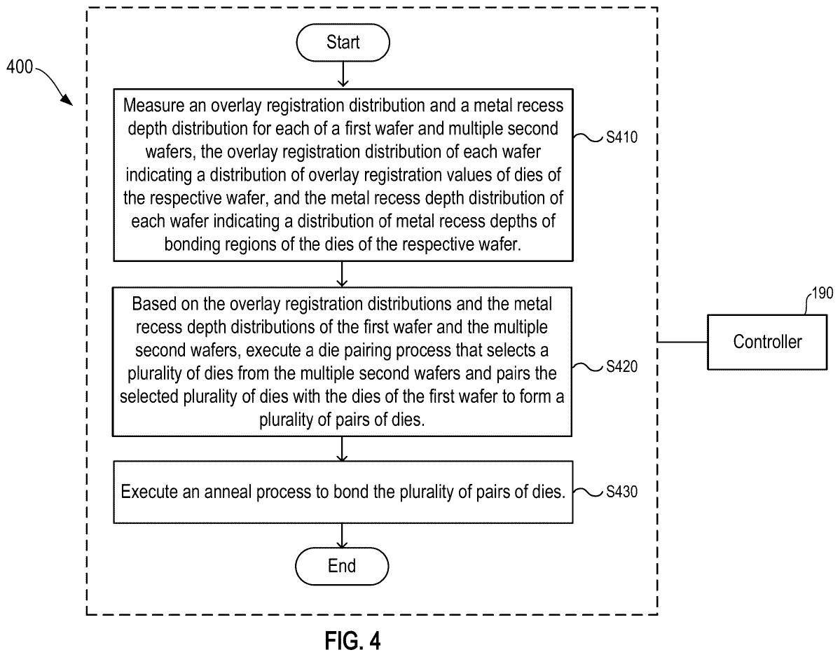

FIG. 4 shows a flow chart of a process for manufacturing a semiconductor device in accordance with some embodiments of the present disclosure. In various embodiments, some of the steps of the process 400 shown can be performed concurrently or in a different order than shown, can be substituted by other method steps, or can be omitted. Additional method steps can also be performed as desired.

Starting at S410, the process 400 can measure an overlay registration distribution and a metal recess depth distribution for each of a first wafer and multiple second wafers, the overlay registration distribution of each wafer indicating a distribution of overlay registration values of dies of the respective wafer, and the metal recess depth distribution of each wafer indicating a distribution of metal recess depths of bonding regions of the dies of the respective wafer.

At step S420, the process 400 can based on the overlay registration distributions and the metal recess depth distributions of the first wafer and the multiple second wafers, execute a die pairing process that selects a plurality of dies from the multiple second wafers and pairs the selected plurality of dies with the dies of the first wafer to form a plurality of pairs of dies.

At step S430, the process 400 can execute an anneal process to bond the plurality of pairs of dies.

It can be recognized that the controller 190 may be coupled to various components of the process 400 to receive inputs from and provide outputs to the components. For example, the controller 190 can be configured to implement steps S410, S420, and/or S430. Of course, one or more functions of the controller 190 can also be manually accomplished.

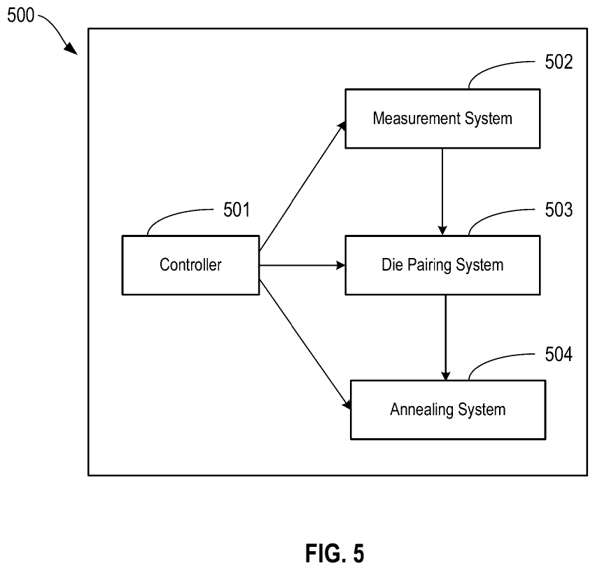

FIG. 5 shows a hybrid bonding system 500 in accordance with some embodiments of the present disclosure. The hybrid bonding system 500 includes a controller 501, a measurement system 502, a die pairing system 503, and an annealing system 604. The measurement system 502 can measure an overlay registration distribution and a metal recess depth distribution for each of a first wafer and multiple second wafers, the overlay registration distribution of each wafer indicating a distribution of overlay registration values of dies of the respective wafer, and the metal recess depth distribution of each wafer indicating a distribution of metal recess depths of bonding regions of the dies of the respective wafer. Based on the overlay registration distributions and the metal recess depth distributions of the first wafer and the multiple second wafers, the die pairing system 503 can execute a die pairing process that selects a plurality of dies from the multiple second wafers and pairs the selected plurality of dies with the dies of the first wafer to form a plurality of pairs of dies. The annealing system 604 can execute an anneal process to bond the plurality of pairs of dies.

In an embodiment, the hybrid bonding system 500 can include a wafer dicing system that dices a wafer into a plurality of dices and a die handling system that picks and places the plurality of dies to corresponding positions.

In an embodiment, the controller 501 can control operations of the wafer dicing system, the die handling system, the measurement system 502, the die pairing system 503, and the annealing system 604.

Aspects of the disclosure provide a hybrid bonding method. The hybrid bonding method includes measuring an overlay registration distribution and a metal recess depth distribution for each of a first wafer and multiple second wafers, the overlay registration distribution of each wafer indicating a distribution of overlay registration values of dies of the respective wafer, and the metal recess depth distribution of each wafer indicating a distribution of metal recess depths of bonding regions of the dies of the respective wafer; based on the overlay registration distributions and the metal recess depth distributions of the first wafer and the multiple second wafers, executing a die pairing process that selects a plurality of dies from the multiple second wafers and pairs the selected plurality of dies with the dies of the first wafer to form a plurality of pairs of dies; and executing an anneal process to bond the plurality of pairs of dies.

In an embodiment, in the hybrid bonding method, the bonding region of each die includes a dielectric material and a metal that is recessed below a surface of the dielectric material, and the metal recess depth of the bonding region indicates a recess depth of the metal relative to the surface of the dielectric material of the bonding region.

In an embodiment, in the hybrid bonding method, one die of each pair of dies has a first overlay registration value and the other die of the respective pair of dies has a second overlay registration value, the die pairing process is executed such that a difference between the first and second overlay registration values is within an overlay registration threshold.

In an embodiment, in the hybrid bonding method, one die of each pair of dies has a first metal recess depth and the other die of the respective pair of dies has a second metal recess depth, the die pairing process is executed such that a sum of the first and second metal recess values is within a predetermined range.

In an embodiment, in the hybrid bonding method, the die pairing process includes: determining an allowed overlay registration distribution based on the overlay registration distribution of the first wafer; determining an allowed metal recess depth distribution based on the metal recess depth distribution of the first wafer; and selecting the plurality of dies from the multiple second wafers based on the allowed overlay registration distribution and the allowed metal recess depth distribution.

In an embodiment, in the hybrid bonding method, the plurality of dies is selected from the multiple second wafers based on the allowed overlay registration distribution being prioritized to the allowed metal recess depth distribution.

In an embodiment, in the hybrid bonding method, the plurality of dies is selected from the multiple second wafers based on the allowed metal recess depth distribution being prioritized to the allowed overlay registration distribution.

In an embodiment, in the hybrid bonding method, the die pairing process is executed based on a failure analysis of previous bonding data.

In an embodiment, in the hybrid bonding method, the bonding the plurality of pairs of dies includes: placing the plurality of pairs of dies such that the bonding region of one die of each pair of dies is opposed to the bonding region of the other die of the respective pair of dies; and adjusting parameters of the anneal process such that the opposed bonding regions of each pair of dies are bonded with each other.

In an embodiment, in the hybrid bonding method, the parameters of the anneal process include time and temperature.

Aspects of the disclosure provide a hybrid bonding system. The hybrid bonding system includes a controller configured to control a measurement system to measure an overlay registration distribution and a metal recess depth distribution for each of a first wafer and multiple second wafers, the overlay registration distribution of each wafer indicating a distribution of overlay registration values of dies of the respective wafer, and the metal recess depth distribution of each wafer indicating a distribution of metal recess depths of bonding regions of the dies of the respective wafer; based on the overlay registration distributions and the metal recess depth distributions of the first wafer and the multiple second wafers, control a die pairing system to execute a die pairing process that selects a plurality of dies from the multiple second wafers and pairs the selected plurality of dies with the dies of the first wafer to form a plurality of pairs of dies; and control an anneal system to execute an anneal process to bond the plurality of pairs of dies.

In an embodiment, in the hybrid bonding system, the bonding region of each die includes a dielectric material and a metal that is recessed below a surface of the dielectric material, and the metal recess depth of the bonding region indicates a recess depth of the metal relative to the surface of the dielectric material of the bonding region.

In an embodiment, in the hybrid bonding system, one die of each pair of dies has a first overlay registration value and the other die of the respective pair of dies has a second overlay registration value, the die pairing process is executed such that a difference between the first and second overlay registration values is within an overlay registration threshold.

In an embodiment, in the hybrid bonding system, one die of each pair of dies has a first metal recess depth and the other die of the respective pair of dies has a second metal recess depth, the die pairing process is executed such that a sum of the first and second metal recess values is within a predetermined range.

In an embodiment, in the hybrid bonding system, the die pairing process includes: determining an allowed overlay registration distribution based on the overlay registration distribution of the first wafer; determining an allowed metal recess depth distribution based on the metal recess depth distribution of the first wafer; and selecting the plurality of dies from the multiple second wafers based on the allowed overlay registration distribution and the allowed metal recess depth distribution.

In an embodiment, in the hybrid bonding system, the plurality of dies is selected from the multiple second wafers based on the allowed overlay registration distribution being prioritized to the allowed metal recess depth distribution.

In an embodiment, in the hybrid bonding system, the plurality of dies is selected from the multiple second wafers based on the allowed metal recess depth distribution being prioritized to the allowed overlay registration distribution.

In an embodiment, in the hybrid bonding system, the die pairing process is executed based on a failure analysis of previous bonding data.

In an embodiment, in the hybrid bonding system, the bonding the plurality of pairs of dies includes: placing the plurality of pairs of dies such that the bonding region of one die of each pair of dies is opposed to the bonding region of the other die of the respective pair of dies; and adjusting parameters of the anneal process such that the opposed bonding regions of each pair of dies are bonded with each other.

In an embodiment, in the hybrid bonding system, the parameters of the anneal process include time and temperature.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the present disclosure. The substrate may include any material portion or structure of a device, particularly a semiconductor or other electronics device, and may, for example, be a base substrate structure, such as a semiconductor wafer, reticle, or a dielectric layer on or overlying a base substrate structure such as a thin film. Thus, substrate is not limited to any particular base structure, underlying dielectric layer or overlying dielectric layer, patterned or un-patterned, but rather, is contemplated to include any such dielectric layer or base structure, and any combination of dielectric layers and/or base structures. The description may reference particular types of substrates, but this is for illustrative purposes only.

Those skilled in the art will also understand that there can be many variations made to the operations of the techniques explained above while still achieving the same objectives of the present disclosure. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A hybrid bonding method, comprising:
measuring an overlay registration distribution and a metal recess depth distribution for each of a first wafer and multiple second wafers, the overlay registration distribution of each wafer indicating a distribution of overlay registration values of dies of the respective wafer, and the metal recess depth distribution of each wafer indicating a distribution of metal recess depths of bonding regions of the dies of the respective wafer;
based on the overlay registration distributions and the metal recess depth distributions of the first wafer and the multiple second wafers, executing a die pairing process that selects a plurality of dies from the multiple second wafers and pairs the selected plurality of dies with the dies of the first wafer to form a plurality of pairs of dies; and
executing an anneal process to bond the plurality of pairs of dies.

2. The hybrid bonding method of claim 1, wherein the bonding region of each die includes a dielectric material and a metal that is recessed below a surface of the dielectric material, and the metal recess depth of the bonding region indicates a recess depth of the metal relative to the surface of the dielectric material of the bonding region.

3. The hybrid bonding method of claim 1, wherein one die of each pair of dies has a first overlay registration value and the other die of the respective pair of dies has a second overlay registration value, the die pairing process is executed such that a difference between the first and second overlay registration values is within an overlay registration threshold.

4. The hybrid bonding method of claim 1, wherein one die of each pair of dies has a first metal recess depth and the other die of the respective pair of dies has a second metal recess depth, the die pairing process is executed such that a sum of the first and second metal recess values is within a predetermined range.

5. The hybrid bonding method of claim 1, wherein the die pairing process includes:
determining an allowed overlay registration distribution based on the overlay registration distribution of the first wafer;
determining an allowed metal recess depth distribution based on the metal recess depth distribution of the first wafer; and
selecting the plurality of dies from the multiple second wafers based on the allowed overlay registration distribution and the allowed metal recess depth distribution.

6. The hybrid bonding method of claim 5, wherein the plurality of dies is selected from the multiple second wafers based on the allowed overlay registration distribution being prioritized to the allowed metal recess depth distribution.

7. The hybrid bonding method of claim 5, wherein the plurality of dies is selected from the multiple second wafers based on the allowed metal recess depth distribution being prioritized to the allowed overlay registration distribution.

8. The hybrid bonding method of claim 1, wherein the die pairing process is executed based on a failure analysis of previous bonding data.

9. The hybrid bonding method of claim 1, wherein the bonding the plurality of pairs of dies includes:
placing the plurality of pairs of dies such that the bonding region of one die of each pair of dies is opposed to the bonding region of the other die of the respective pair of dies; and
adjusting parameters of the anneal process such that the opposed bonding regions of each pair of dies are bonded with each other.

10. The hybrid bonding method of claim 6, wherein the parameters of the anneal process include time and temperature.

11. A hybrid bonding system, comprising:
a controller configured to
control a measurement system to measure an overlay registration distribution and a metal recess depth distribution for each of a first wafer and multiple second wafers, the overlay registration distribution of each wafer indicating a distribution of overlay registration values of dies of the respective wafer, and the metal recess depth distribution of each wafer indicating a distribution of metal recess depths of bonding regions of the dies of the respective wafer;
based on the overlay registration distributions and the metal recess depth distributions of the first wafer and the multiple second wafers, control a die pairing system to execute a die pairing process that selects a plurality of dies from the multiple second wafers and pairs the selected plurality of dies with the dies of the first wafer to form a plurality of pairs of dies; and
control an anneal system to execute an anneal process to bond the plurality of pairs of dies.

12. The hybrid bonding system of claim 11, wherein the bonding region of each die includes a dielectric material and a metal that is recessed below a surface of the dielectric material, and the metal recess depth of the bonding region indicates a recess depth of the metal relative to the surface of the dielectric material of the bonding region.

13. The hybrid bonding system of claim 11, wherein one die of each pair of dies has a first overlay registration value and the other die of the respective pair of dies has a second overlay registration value, the die pairing process is executed such that a difference between the first and second overlay registration values is within an overlay registration threshold.

14. The hybrid bonding system of claim 11, wherein one die of each pair of dies has a first metal recess depth and the other die of the respective pair of dies has a second metal recess depth, the die pairing process is executed such that a sum of the first and second metal recess values is within a predetermined range.

15. The hybrid bonding system of claim 11, wherein the die pairing process includes:
determining an allowed overlay registration distribution based on the overlay registration distribution of the first wafer;
determining an allowed metal recess depth distribution based on the metal recess depth distribution of the first wafer; and
selecting the plurality of dies from the multiple second wafers based on the allowed overlay registration distribution and the allowed metal recess depth distribution.

16. The hybrid bonding system of claim 15, wherein the plurality of dies is selected from the multiple second wafers based on the allowed overlay registration distribution being prioritized to the allowed metal recess depth distribution.

17. The hybrid bonding system of claim 15, wherein the plurality of dies is selected from the multiple second wafers based on the allowed metal recess depth distribution being prioritized to the allowed overlay registration distribution.

18. The hybrid bonding system of claim 11, wherein the die pairing process is executed based on a failure analysis of previous bonding data.

19. The hybrid bonding system of claim 11, wherein the bonding the plurality of pairs of dies includes:
placing the plurality of pairs of dies such that the bonding region of one die of each pair of dies is opposed to the bonding region of the other die of the respective pair of dies; and
adjusting parameters of the anneal process such that the opposed bonding regions of each pair of dies are bonded with each other.

20. The hybrid bonding system of claim 16, wherein the parameters of the anneal process include time and temperature.
